(19) United States
(12) Patent Application Publication
(10) Pub. No.: US 2026/0362793 A1
(43) Pub. Date: Nov. 12, 2026

(54) FIELD EFFECT TRANSISTOR WITH ELECTRODE UNDERNEATH CHANNEL

(71) Applicant: INTERNATIONAL BUSINESS MACHINES CORPORATION, Armonk, NY (US)

(72) Inventors: Fabio Carta, Pleasantville, NY (US); Pouya Hashemi, Purchase, NY (US); Paul Michael Solomon, Yorktown Heights, NY (US); Babar Khan, Ossining, NY (US); Martin Michael Frank, Dobbs Ferry, NY (US)

(21) Appl. No.: 19/202,112

(22) Filed: May 8, 2025

(51) Int. Cl. H10D 84/83; H10D 30/01; H10D 30/60; H10D 30/63; H10D 62/40; H10D 62/832; H10D 64/62; H10D 84/01; H10W 20/42

(52) U.S. Cl. CPC H10D 84/83125; H10D 30/025; H10D 30/027; H10D 30/611; H10D 30/63; H10D 62/40; H10D 62/832; H10D 64/62; H10D 84/0133; H10D 84/0149; H10D 84/837; H10W 20/42

(57) ABSTRACT

Embodiments of present invention provide a semiconductor structure. The semiconductor structure includes a field-effect-transistor (FET) embedded in a dielectric layer on top a back-end-of-line stack; and one or more electrodes conductively connected to the FET, where a first electrode of the one or more electrodes is directly underneath a layer of crystallized semiconductor material. In one embodiment, the FET is a vertical FET and the first electrode is conductively connected to a source/drain region of the vertical FET, the source/drain region being formed in the layer of crystallized semiconductor material. In another embodiment, the FET is a planar FET and the first electrode includes an electrical contact and a back-gate of the planar FET in direct contact with the electrical contact.

### BACKGROUND

The present application relates to manufacturing of semiconductor integrated circuits. More particularly, it relates to method of forming electrode underneath channel region of field-effect-transistors and the structure formed thereby.

Power gating devices are commonly used in microprocessor to control power delivery from a C4 bump to a circuit sub-block. These devices allow for switching off part of the cores of a microprocessor thereby decreasing power consumption and heat dissipation

Power gating devices are generally integrated in the front-end-of-line (FEOL) area, which therefore suffer from large parasitic resistive drop. This type of resistive drop, known as IR of current over resistance, limits the performance of devices. Moreover, when being placed in the FEOL area, the power gating devices are highly constrained by the existence of various logic circuitry and metal lines in the area, which inhibits optimal placement of these devices.

### SUMMARY

Embodiments of present invention provide a semiconductor structure. The semiconductor structure includes a field-effect-transistor (FET) embedded in a dielectric layer on top a back-end-of-line stack; and one or more electrodes conductively connected to the FET, where a first electrode of the one or more electrodes is directly underneath a layer of crystallized semiconductor material.

In one embodiment, the FET is a vertical FET and the first electrode is conductively connected to a source/drain region of the vertical FET, the source/drain region being formed in the layer of crystallized semiconductor material. In a further embodiment, the first electrode is in direct contact with a diffusion barrier layer, and the diffusion barrier layer is in direct contact with the layer of crystallized semiconductor material.

In another embodiment, the FET is a planar FET and the first electrode includes an electrical contact and a back-gate of the planar FET in direct contact with the electrical contact. In a further embodiment, the back-gate of the planar FET is vertically underneath a channel region of the planar FET.

According to one embodiment, the semiconductor structure further includes a via embedded in the dielectric layer at a level below the layer of crystallized semiconductor material, the via includes at least one material that is substantially same as the crystallized semiconductor material.

In one embodiment, the via further includes a material in an amorphous state, the material, except being in the amorphous state, being substantially same as the crystallized semiconductor material.

Embodiments of present invention provide a method of forming a semiconductor structure. The method includes providing a supporting structure, the supporting structure including a substrate and a back-end-of-line stack; forming a backside electrode in a dielectric layer on top of the supporting structure; forming an amorphous silicon layer on top of the backside electrode and crystallizing the amorphous silicon layer into a crystalline silicon layer; patterning the crystalline silicon layer into a first part of a transistor; forming a metal gate on top of the crystalline silicon layer; and finishing forming the transistor.

In one embodiment, the transistor is a vertical transistor and the first part is a first source/drain region, and forming the metal gate includes forming a first spacer layer on top of the crystalline silicon layer; forming a gate metal layer on top of the first spacer layer; forming a second spacer layer on top of the gate metal layer; creating an opening inside the gate metal layer, the opening exposing the first source/drain region; forming a gate dielectric at sidewalls of the opening inside the gate metal layer; and forming a channel region by filling the opening with doped channel material. In a further embodiment, finishing forming the transistor includes forming a second source/drain above the gate metal layer and next to the channel region; and forming a top electrode in contact with the second source/drain region of the vertical transistor.

In another embodiment, the transistor is a planar transistor and the first part is a channel region of the planar transistor, and forming the metal gate includes forming a gate dielectric layer on top of the channel region; forming a gate metal layer on top of the gate dielectric layer; patterning the gate metal layer and the gate dielectric layer into a metal gate; and forming sidewall spacers at sidewalls of the metal gate.

In one embodiment, finishing forming the transistor includes forming a first and a second source/drain region in the crystalline silicon layer adjacent to the sidewall spacers; covering the first and the second source/drain region with a layer of dielectric material; forming a first and a second source/drain contact in contact with the first and the second source/drain region respectively; forming a backside contact in contact with the backside electrode; and forming a gate contact in contact with the metal gate of the planar transistor.

Embodiments of present invention provide a semiconductor structure. The semiconductor structure includes a FET embedded in a dielectric layer on top of a substrate; and one or more electrodes conductively connected to the FET, where a first electrode of the one or more electrodes is directly underneath a layer of crystallized material and a portion of the layer of crystallized material is a part of the FET.

In one embodiment, the FET is a vertical FET and the first electrode is conductively connected to a bottom source/drain region of the vertical FET, and the portion of the layer of crystallized material forms the bottom source/drain region. In a further embodiment, the first electrode is conductively connected to the bottom source/drain region of the vertical FET via a diffusion barrier layer, the diffusion barrier layer containing WN, TiN, or TaN.

In another embodiment, the FET is a planar FET and the first electrode includes an electrical contact and a back-gate of the planar FET in direct contact with the electrical contact. In a further embodiment, the back-gate of the planar FET is vertically underneath a channel region of the planar FET and is formed from a portion of the first electrode.

According to one embodiment, the semiconductor structure further includes a via embedded in a dielectric layer at a level below the layer of crystallized material, the via includes at least one material that is substantially same as the crystallized material.

In one embodiment, the via further includes a material in an amorphous state, the material, excepting being in the amorphous state, being substantially same as the crystallized material.

In one embodiment, the crystallized material is a crystallized silicon or a crystallized silicon-germanium.

### BRIEF DESCRIPTION OF THE DRAWINGS

The present invention will be understood and appreciated more fully from the following detailed description of embodiments of present invention, taken in conjunction with accompanying drawings of which:

FIGS. 1A and 1B are demonstrative illustrations of cross-sectional views of a semiconductor structure at a step of manufacturing thereof according to one embodiment of present invention;

FIGS. 2A and 2B are demonstrative illustrations of cross-sectional views of a semiconductor structure at a step of manufacturing thereof, following the step illustrated in FIGS. 1A and 1B, according to one embodiment of present invention;

FIGS. 3A and 3B are demonstrative illustrations of cross-sectional views of a semiconductor structure at a step of manufacturing thereof, following the step illustrated in FIGS. 2A and 2B, according to one embodiment of present invention;

FIGS. 4A and 4B are demonstrative illustrations of cross-sectional views of a semiconductor structure at a step of manufacturing thereof, following the step illustrated in FIGS. 3A and 3B, according to one embodiment of present invention;

FIGS. 5A and 5B are demonstrative illustrations of cross-sectional views of a semiconductor structure at a step of manufacturing thereof, following the step illustrated in FIGS. 4A and 4B, according to one embodiment of present invention;

FIGS. 6A and 6B are demonstrative illustrations of cross-sectional views of a semiconductor structure at a step of manufacturing thereof, following the step illustrated in FIGS. 5A and 5B, according to one embodiment of present invention;

FIGS. 7A and 7B are demonstrative illustrations of cross-sectional views of a semiconductor structure at a step of manufacturing thereof, following the step illustrated in FIGS. 6A and 6B, according to one embodiment of present invention;

FIGS. 8A and 8B are demonstrative illustrations of cross-sectional views of a semiconductor structure at a step of manufacturing thereof, following the step illustrated in FIGS. 7A and 7B, according to one embodiment of present invention;

FIGS. 9A and 9B are demonstrative illustrations of cross-sectional views of a semiconductor structure at a step of manufacturing thereof, following the step illustrated in FIGS. 8A and 8B, according to one embodiment of present invention;

FIGS. 10A and 10B are demonstrative illustrations of cross-sectional views of a semiconductor structure at a step of manufacturing thereof, following the step illustrated in FIGS. 9A and 9B, according to one embodiment of present invention;

FIGS. 11A and 11B are demonstrative illustrations of cross-sectional views of a semiconductor structure at a step of manufacturing thereof, following the step illustrated in FIGS. 10A and 10B, according to one embodiment of present invention;

FIGS. 12A and 12B are demonstrative illustrations of cross-sectional views of a semiconductor structure at a step of manufacturing thereof, following the step illustrated in FIGS. 11A and 11B, according to one embodiment of present invention;

FIGS. 13A and 13B are demonstrative illustrations of cross-sectional views of a semiconductor structure at a step of manufacturing thereof according to another embodiment of present invention;

FIGS. 14A and 14B are demonstrative illustrations of cross-sectional views of a semiconductor structure at a step of manufacturing thereof, following the step illustrated in FIGS. 13A and 13B, according to another embodiment of present invention;

FIGS. 15A and 15B are demonstrative illustrations of cross-sectional views of a semiconductor structure at a step of manufacturing thereof, following the step illustrated in FIGS. 14A and 14B, according to another embodiment of present invention;

FIGS. 16A and 16B are demonstrative illustrations of cross-sectional views of a semiconductor structure at a step of manufacturing thereof, following the step illustrated in FIGS. 15A and 15B, according to another embodiment of present invention;

FIGS. 17A and 17B are demonstrative illustrations of cross-sectional views of a semiconductor structure at a step of manufacturing thereof, following the step illustrated in FIGS. 16A and 16B, according to another embodiment of present invention;

FIGS. 18A and 18B are demonstrative illustrations of cross-sectional views of a semiconductor structure at a step of manufacturing thereof, following the step illustrated in FIGS. 17A and 17B, according to another embodiment of present invention;

FIGS. 19A and 19B are demonstrative illustrations of cross-sectional views of a semiconductor structure at a step of manufacturing thereof, following the step illustrated in FIGS. 18A and 18B, according to another embodiment of present invention;

FIGS. 20A and 20B are demonstrative illustrations of cross-sectional views of a semiconductor structure at a step of manufacturing thereof, following the step illustrated in FIGS. 19A and 19B, according to another embodiment of present invention;

FIGS. 21A and 21B are demonstrative illustrations of cross-sectional views of a semiconductor structure at a step of manufacturing thereof, following the step illustrated in FIGS. 20A and 20B, according to another embodiment of present invention; and

FIG. 22 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms "about" or "substantially" as used herein with regard to thicknesses, widths, percentages, ranges, etc., are meant to denote being close or approximate to, but not exactly. For example, the term "about" or "substantially" as used herein implies that a small margin of error may be present such as, by way of example only, 1% or less than the stated amount. Likewise, the terms "on", “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

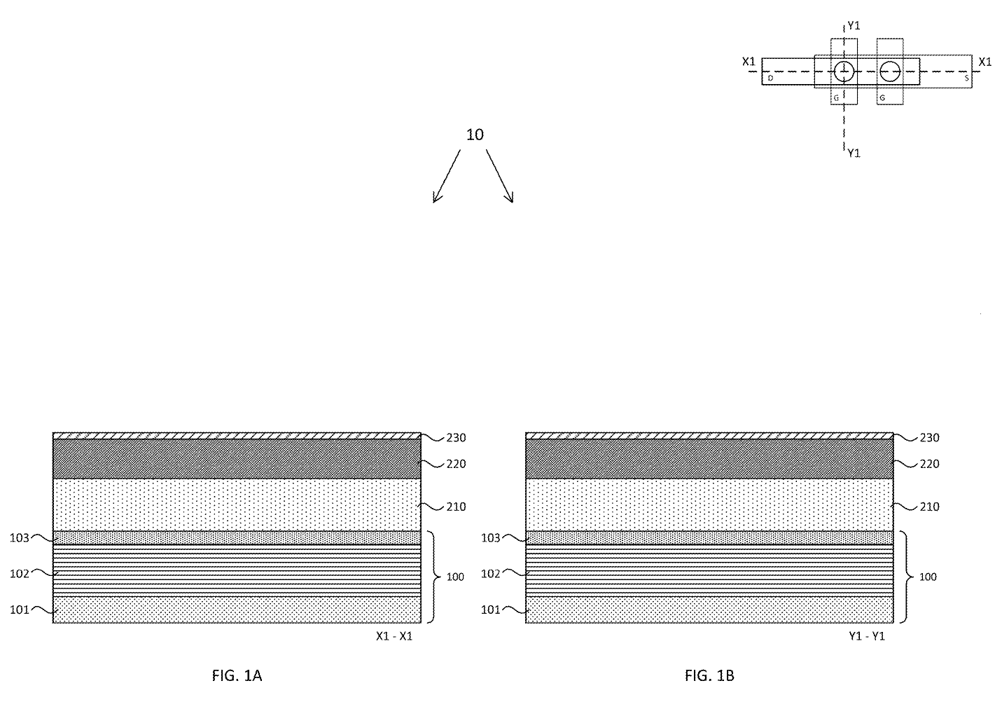

FIGS. 1A and 1B are demonstrative illustrations of different cross-sectional views of a semiconductor structure 10 in a step of manufacturing thereof according to one embodiment of present invention. More specifically, FIG. 1A illustrates a cross-sectional view of the semiconductor structure 10 with a cross-section made along a dashed line X1-X1 as illustrated in a simplified top view of the semiconductor structure 10 at the up-right corner of the drawing. FIG. 1B illustrates a cross-sectional view of the semiconductor structure 10 with a cross-section made along a dashed line Y1-Y1, as illustrated in the simplified top view, and made in a direction perpendicular to the cross-section illustrated in FIG. 1A.

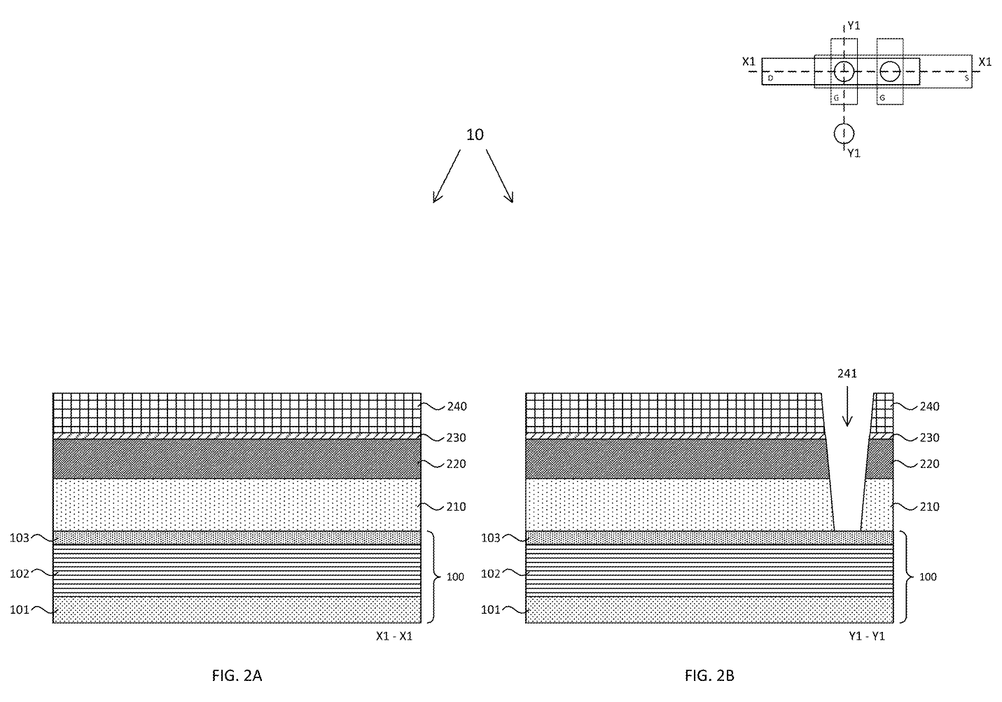

Likewise, FIGS. 2A and 2B-12A and 12B are demonstrative illustrations of cross-sectional views of the semiconductor structure 10, at different manufacturing steps, that are illustrated in manners similar to FIGS. 1A and 1B respectively.

Embodiments of present invention provide forming a semiconductor structure 10 that is demonstratively illustrated to start with a supporting structure 100. The supporting structure 100 may include, for example, a substrate 101 and a back-end-of-line (BEOL) stack 102 on top of the substrate 101. The substrate 101 may include active devices such as front-end-of-line (FEOL) devices formed therein. In one embodiment, the supporting structure 100 may further include a capping layer 103 on top of the BEOL stack 102. The capping layer 103 may include or be made of, for example, silicon-nitride (SiN).

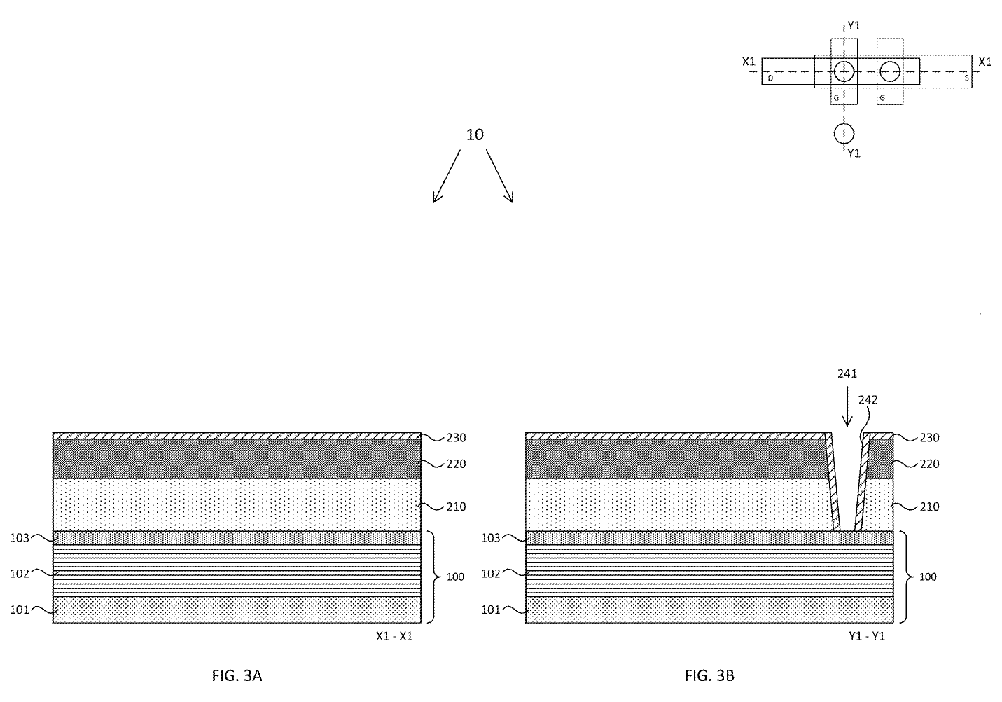

Embodiments of present invention further provide forming a dielectric layer 210 on top of the capping layer 103, a conductive layer 220 such as a metallic layer on top of the dielectric layer 210, and a diffusion barrier layer 230 on top of the conductive layer 220. The diffusion barrier layer 230 may be formed such that semiconductor material layer(s), to be formed later on top thereof, may not experience excessive metal contamination potentially caused by the conductive layer 220, particularly during a laser annealing process of the semiconductor material layer(s) as being discussed below in more details. In one embodiment, the diffusion barrier layer 230 may be formed at a later stage (see FIGS. 3A and 3B) after an opening 241 is created in the conductive layer 220 and the dielectric layer 210. In this case, the diffusion barrier layer 230 may be formed together with, or separately from, a spacer 242.

In one embodiment, the diffusion barrier layer 230 may contain, include, or be made of, for example, tungsten-nitride (WN), titanium-nitride (TiN), or tantalum-nitride (TaN). The conductive layer 220 may contain, include, or be made of copper (Cu), cobalt (Co), aluminum (Al), tungsten (W) or other conductive materials. The dielectric layer 210 may contain, include, or be made of silicon-oxide (SiOx), silicon-carbide (SiC), silicon-carbonitride (SiCN), silicon-oxycarbide (SiOC), or other suitable materials. In one embodiment, the diffusion barrier layer 230 may have a thickness ranging from about 5nm to about 10nm; the conductive layer 220 may have a thickness ranging from about 50nm to about 100nm; and the dielectric layer 210 may have a thickness ranging from about 250nm to about 1um (micrometer).

FIGS. 2A and 2B are demonstrative illustrations of cross-sectional views of a semiconductor structure at a step of manufacturing thereof, following the step illustrated in FIGS. 1A and 1B, according to one embodiment of present invention. More particularly, embodiments of present invention provide applying, for example, a lithographic patterning process to form a mask 240, which may include a photoresist mask on top of a hard mask. The mask 240 may include a pattern such as an opening and the opening may subsequently be transferred, through a selective etch process, onto the diffusion barrier layer 230, the conductive layer 220, and the dielectric layer 210 to form an opening 241. The selective etch process may be stopped when the capping layer 103 is exposed by the opening 241. In other words, the capping layer 103 may work as an etch-stop-layer (ESL) in the selective etch process.

FIGS. 3A and 3B are demonstrative illustrations of cross-sectional views of a semiconductor structure at a step of manufacturing thereof, following the step illustrated in FIGS. 2A and 2B, according to one embodiment of present invention. More particularly, embodiments of present invention provide removing the mask 240 from the top of the diffusion barrier layer 230 and forming, subsequently, a spacer 242 at sidewall of the opening 241. The spacer 242 may be formed through first forming a conformal layer of diffusion blocking material such as, for example, WN, TiN, or TaN. Next, the conformal layer may be etched by a directional/anisotropic etch process, such as a reactive-ion-etch (RIE) process, to remove horizontal portions thereof, leaving vertical portion of the conformal layer to form the spacer 242. In one embodiment, the diffusion barrier layer 230 may be formed at this stage as well.

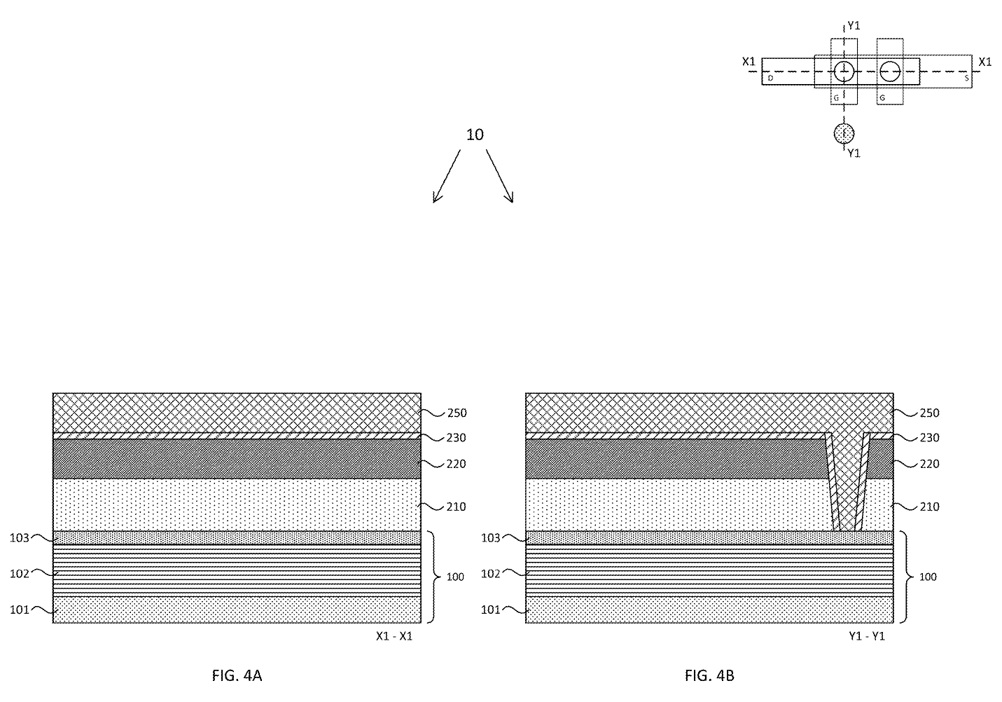

FIGS. 4A and 4B are demonstrative illustrations of cross-sectional views of a semiconductor structure at a step of manufacturing thereof, following the step illustrated in FIGS. 3A and 3B, according to one embodiment of present invention. More particularly, embodiments of present invention provide depositing amorphous silicon in the opening 241 and on top of the diffusion barrier layer 230 thereby forming an amorphous silicon layer 250. The amorphous silicon layer 250 may be deposited through, for example, a physical-vapor-deposition (PVD) process, a chemical-vapor-deposition (CVD) process, or an atomic-layer-deposition (ALD) process. After the deposition, either positive (p+) or negative (n-) ion implantation may be performed to dope the amorphous silicon layer 250 such that materially the amorphous silicon layer 250 may become suitable for forming either p-type or n-type semiconductor transistors such as field-effect-transistors (FET or FETs).

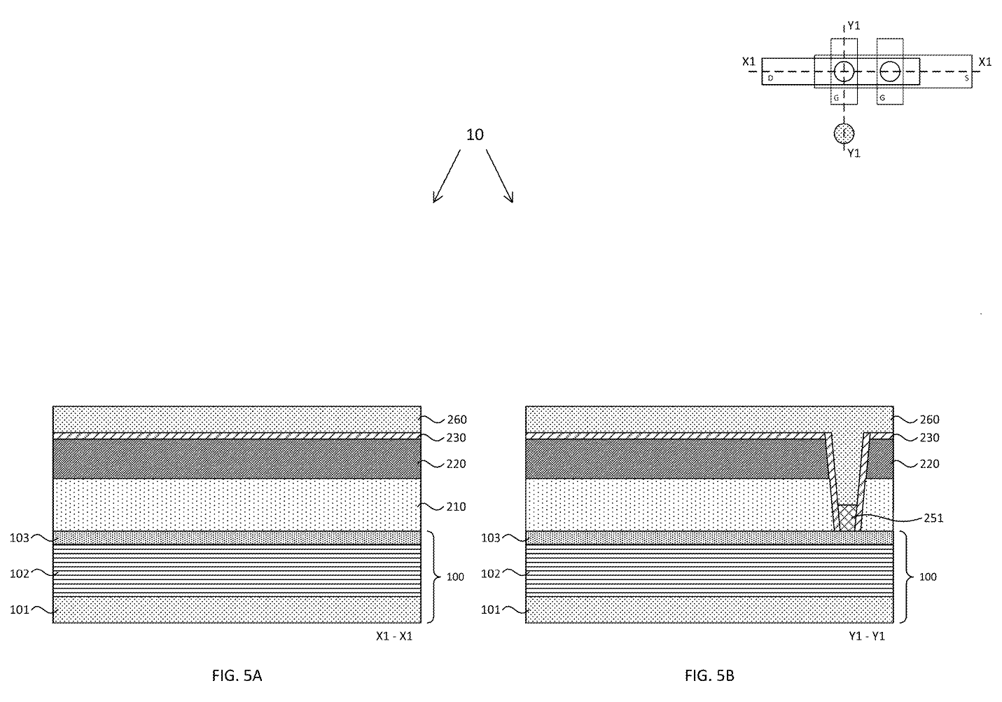

FIGS. 5A and 5B are demonstrative illustrations of cross-sectional views of a semiconductor structure at a step of manufacturing thereof, following the step illustrated in FIGS. 4A and 4B, according to one embodiment of present invention. More particularly, embodiments of present invention provide crystalizing the amorphous silicon layer 250 through an annealing process such as a laser annealing process. The crystallization process may turn the amorphous silicon layer 250 and, for example, more than half of the amorphous silicon in the opening 241 into crystallized semiconductor material such as a crystalline silicon layer 260 with only a fraction 251 of the amorphous silicon remaining at the bottom of the opening 241. Material of the fraction 251 of the amorphous silicon, except being in an amorphous state, is substantially same as material of the crystalline silicon layer 260.

The amorphous silicon in the opening 241 helps the creation of high quality crystalline silicon layer 260. More particularly, the amorphous silicon in the opening 241 may act as nucleation point for the melted silicon, allowing crystal growth to start from the opening 241 whose sidewall, with the high aspect-ratio, subsequently filters to form a single crystalline silicon. During the crystallization process, the diffusion barrier layer 230 and the spacer 242 help prevent or reduce contamination of the crystalline silicon layer 260 caused by possible metallic elements from the conductive layer 220. After the crystallization, a chemical-mechanical-polishing (CMP) process may be applied to planarize a top surface of the crystalline silicon layer 260.

In one embodiment, after the CMP process, the crystalline silicon layer 260 may have a thickness ranging from about 2nm to about 25nm, which is critically important for forming part of one or more field-effect-transistors such as forming source/drain regions of one or more vertical transistors, as being described below in more details.

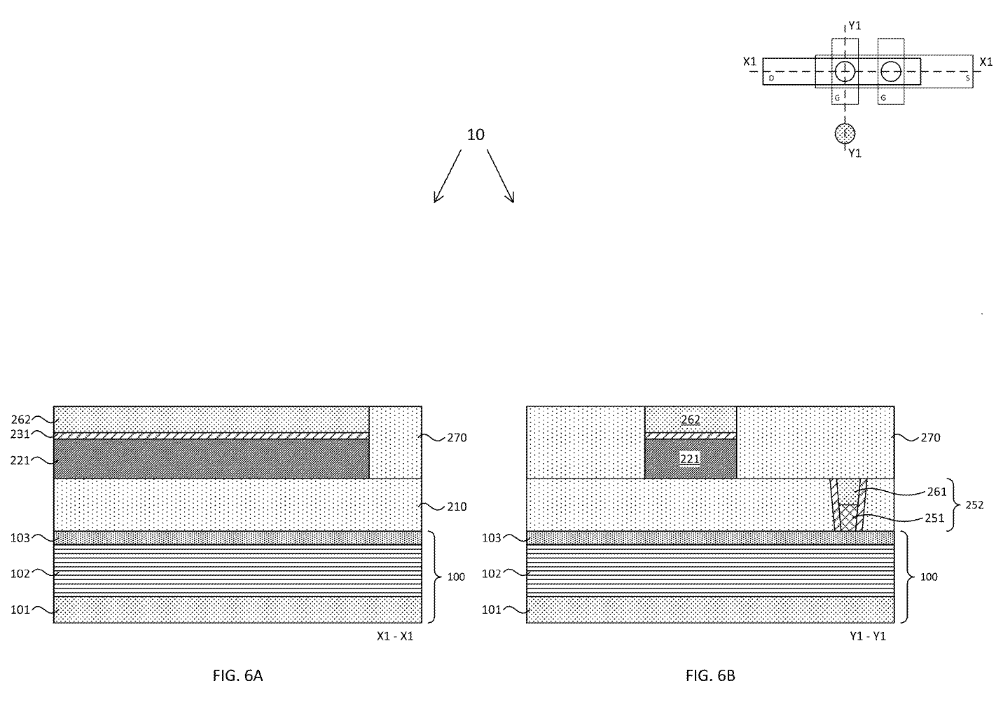

FIGS. 6A and 6B are demonstrative illustrations of cross-sectional views of a semiconductor structure at a step of manufacturing thereof, following the step illustrated in FIGS. 5A and 5B, according to one embodiment of present invention. More particularly, embodiments of present invention provide patterning the conductive layer 220 into a bottom electrode 221 and the crystalline silicon layer 260 on top thereof into a line source/drain area 262. The diffusion barrier layer 230 may consequently become a diffusion barrier layer 231. The patterning process may be a lithographic patterning process, which removes portions of the crystalline silicon layer 260, not-covered by a mask pattern, and the diffusion barrier layer 230 and the conductive layer 220 underneath the crystalline silicon layer 260 with a selective etch process until the dielectric layer 210 is exposed. The patterning process may leave a fraction 261 of the crystalline silicon remaining in the opening 241 above the fraction 251 of the amorphous silicon. After the patterning, dielectric material may be deposited through a CVD process, a PVD process or an ALD process to form a dielectric layer 270 that surround the bottom electrode 221 and the line source/drain area 262. A CMP process may be applied to planarize a top surface of the dielectric layer 270 such that top surfaces of the dielectric layer 270 and the line source/drain area 262 may become coplanar.

In one embodiment, the patterning may create a via 252 at a level below the crystalline silicon layer 260 such as below the line source/drain area 262, and/or below the bottom electrode 221. The via 252 includes the fraction 251 of the amorphous silicon and the fraction 261 of the crystalline silicon. The via 252 is embedded in the dielectric layer 210.

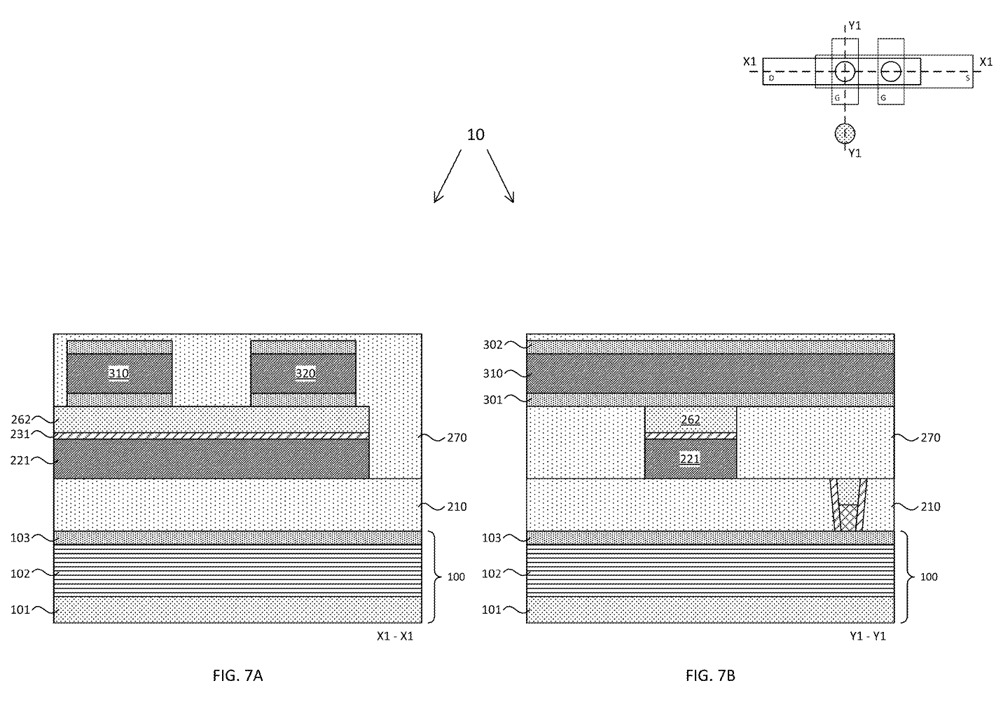

FIGS. 7A and 7B are demonstrative illustrations of cross-sectional views of a semiconductor structure at a step of manufacturing thereof, following the step illustrated in FIGS. 6A and 6B, according to one embodiment of present invention. More particularly, embodiments of present invention provide depositing a first spacer layer 301 on top of the line source/drain area 262 and the dielectric layer 270, a gate metal layer on top of the first spacer layer 301, and a second spacer layer 302 on top of the gate metal layer. The gate metal layer, together with the first and second spacer layers 301 and 302, may subsequently be patterned into a first gate metal 310 and a second gate metal 320 of one or more vertical transistors. The line source/drain area 262 may form one or more source/drain regions, such as one or more bottom source/drain regions, of the one or more vertical transistors respectively.

In one embodiment, the first and second spacer layers 301 and 302 may include or be made of SiN, for example, and each may have a thickness ranging from about 5nm to about 25nm. On the other hand, the first and the second gate metal 310 and 320 may include or be made of W, Co, Cu, and/or TiN and may have a thickness ranging from about 50nm to about 100nm. Next, dielectric material may be deposited or redeposited to be around and/or between the first and the second gate metal 310 and 320 such that the first and the second gate metal 310 and 320 may be embedded in the dielectric layer 270. A CMP process may be applied to planarize a top surface of the dielectric layer 270.

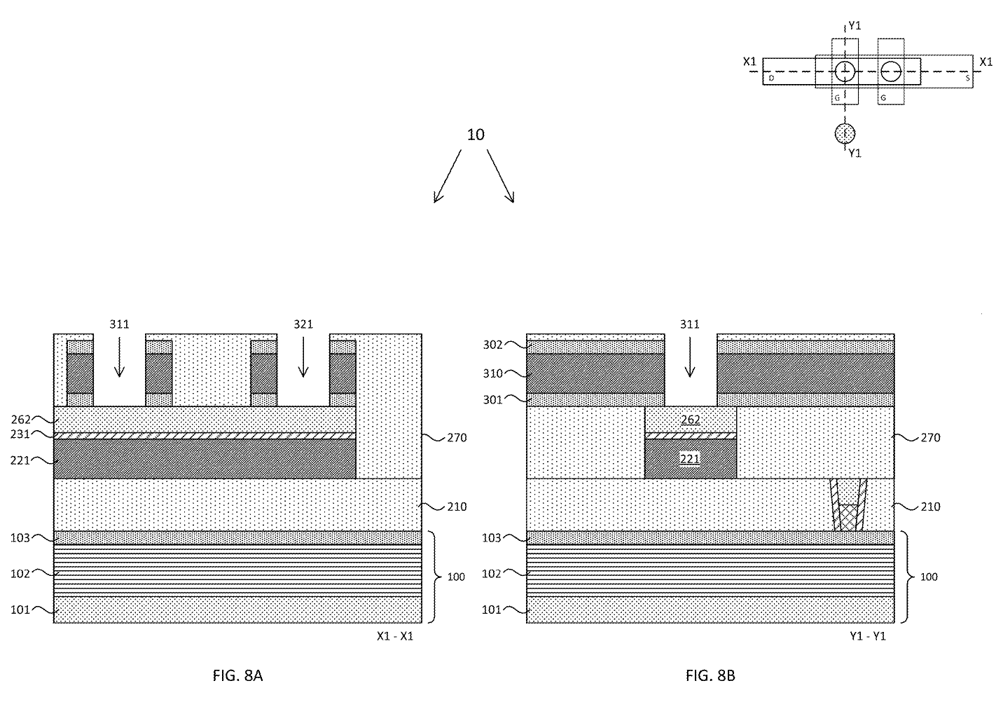

FIGS. 8A and 8B are demonstrative illustrations of cross-sectional views of a semiconductor structure at a step of manufacturing thereof, following the step illustrated in FIGS. 7A and 7B, according to one embodiment of present invention. More particularly, embodiments of present invention provide patterning, through a lithographic patterning and selective etch process, the first and the second gate metal 310 and 320 to create a first and a second channel opening 311 and 321 within the first and the second gate metal 310 and 320. The patterning etches through the second spacer layer 302, the first and the second gate metal 310 and 320 respectively, and the first spacer layer 301 until the underlining line source/drain area 262 is exposed. The exposed portions of the line source/drain area 262 may form bottom source/drain regions of the respective vertical transistors.

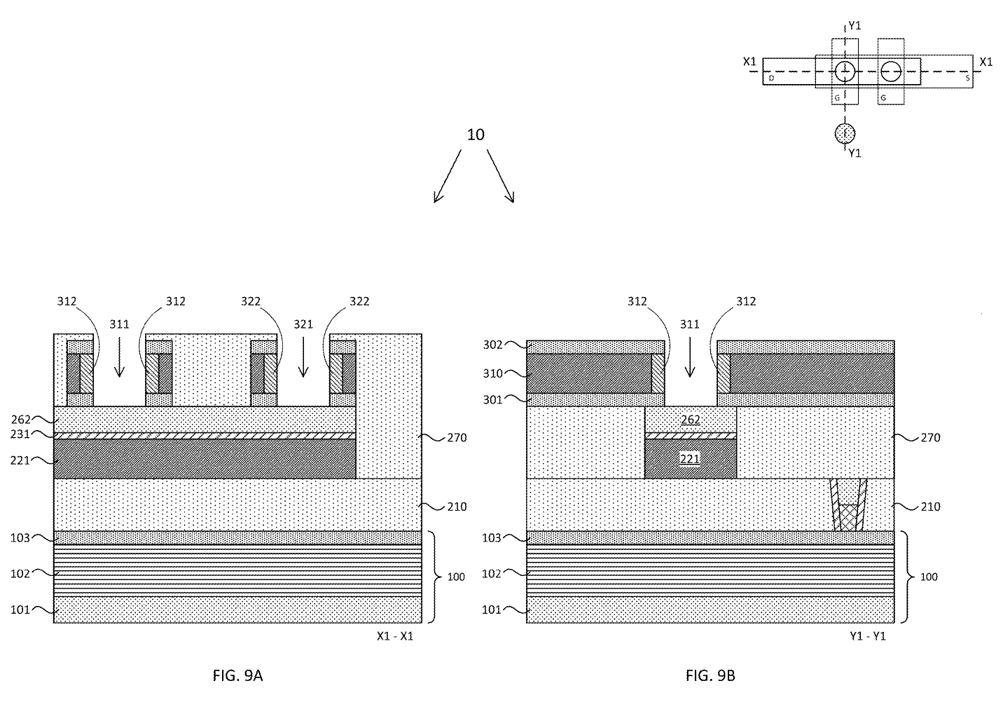

FIGS. 9A and 9B are demonstrative illustrations of cross-sectional views of a semiconductor structure at a step of manufacturing thereof, following the step illustrated in FIGS. 8A and 8B, according to one embodiment of present invention. More particularly, embodiments of present invention provide recessing the first and the second gate metal 310 and 320, horizontally at sidewalls thereof, between the first spacer layer 301 and the second spacer layer 302 to create recesses respectively. Subsequently, high-k dielectric materials, such as hafnium-oxide (HfOx), may be applied to fill the recesses through a deposition process thereby creating a first gate dielectric layer 312 facing the first channel opening 311 and (horizontally) underneath the first gate metal 310. The first gate dielectric layer 312 may surround a first channel region to be formed in the first channel opening 311. Similarly, a second gate dielectric layer 322 may be formed facing the second channel opening 321 and (horizontally) underneath the second gate metal 320. The second gate dielectric layer 322 may surround a second channel region to be formed in the second channel opening 321.

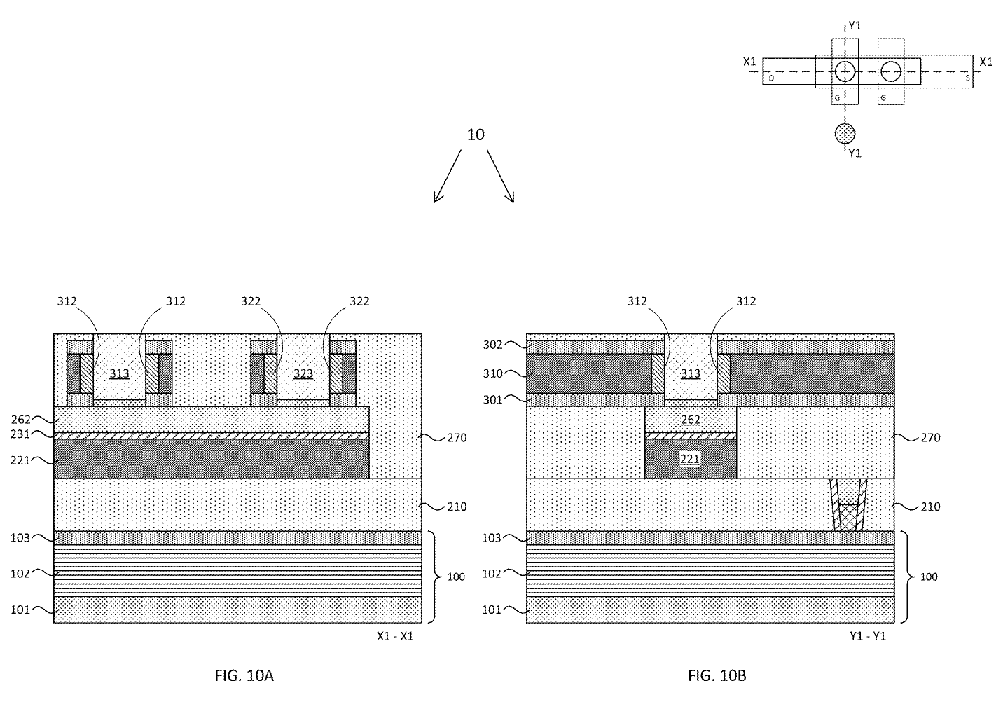

FIGS. 10A and 10B are demonstrative illustrations of cross-sectional views of a semiconductor structure at a step of manufacturing thereof, following the step illustrated in FIGS. 9A and 9B, according to one embodiment of present invention. More particularly, embodiments of present invention provide performing a low-temperature epitaxial growth of silicon, silicon-germanium, or other suitable material with desired positive (p+) or negative (n-) ion doping to form a first channel region 313 in the first channel opening 311, and a second channel region 323 in the second channel opening 321. Consequently, the first channel region 313 is (horizontally) underneath the first gate metal 310 via the first gate dielectric layer 312 and the second channel region 323 is (horizontally) underneath the second gate metal 320 via the second gate dielectric layer 322. A CMP process may be applied to planarize a top surface of the first and the second channel region 313 and 323.

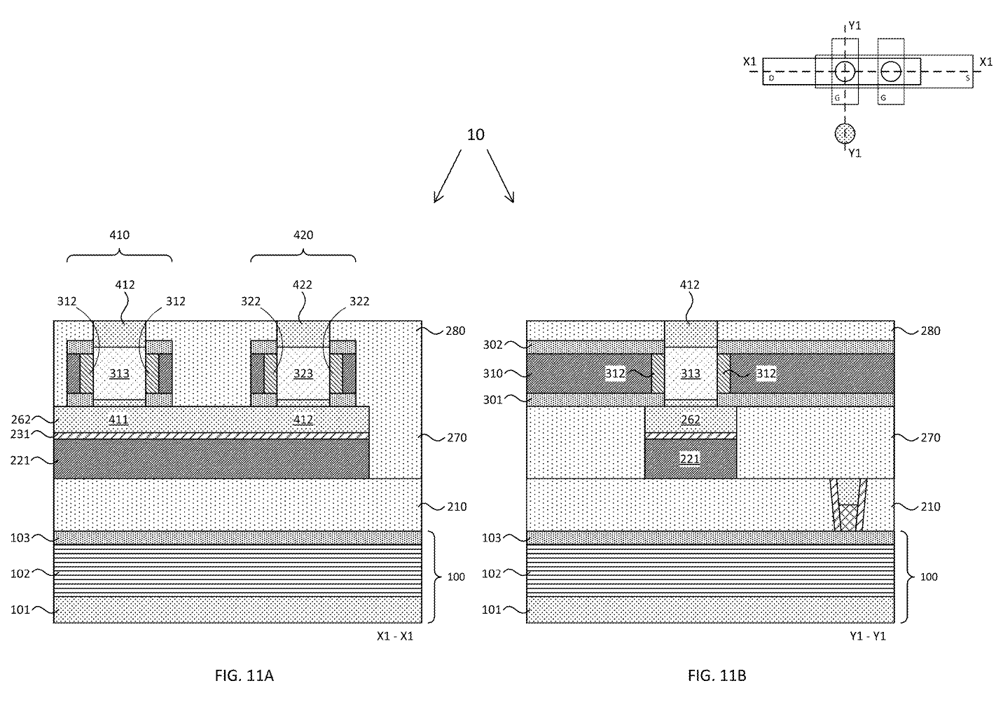

FIGS. 11A and 11B are demonstrative illustrations of cross-sectional views of a semiconductor structure at a step of manufacturing thereof, following the step illustrated in FIGS. 10A and 10B, according to one embodiment of present invention. More particularly, embodiments of present invention provide finishing forming the vertical transistors. For example, embodiments of present invention provide performing desired n- or p+ ion doping to form shallow junction at top portions of the first channel region 313 and the second channel region 323 and subsequently forming a first top source/drain region 412 and a second top source/drain region 422 on top of the respective shallow junctions at the first and the second channel region 313 and 323, thereby forming a first vertical transistor 410 and a second vertical transistor 420. The first vertical transistor 410 may also include a first bottom source/drain region 411 formed in the line source/drain area 262, and the second vertical transistor 420 may also include a second bottom source/drain region 412 formed in the line source/drain area 262 as well. The formed first and second top source/drain regions 412 and 422 may be activated through an annealing process such as a rapid laser annealing (RLA) process. Next, dielectric material may be deposited to form a dielectric layer 280 covering and/or surrounding the first and the second top source/drain region 412 and 422. A CMP process may be applied to polish and expose top surfaces of the first and the second top source/drain region 412 and 422 that are surrounded by the dielectric layer 280.

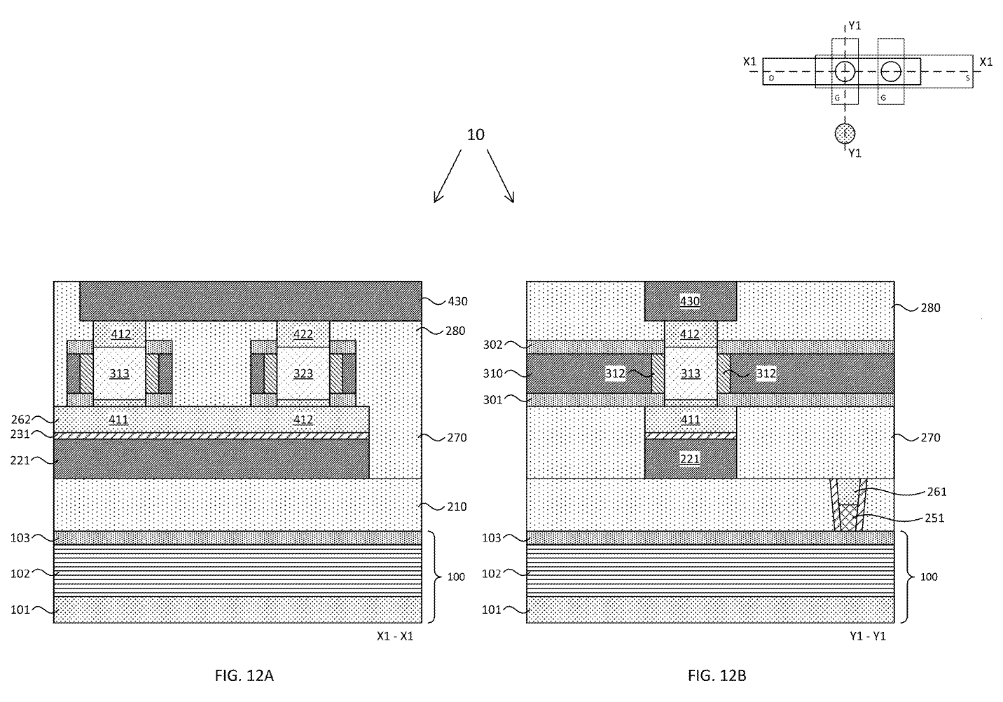

FIGS. 12A and 12B are demonstrative illustrations of cross-sectional views of a semiconductor structure at a step of manufacturing thereof, following the step illustrated in FIGS. 11A and 11B, according to one embodiment of present invention. More particularly, embodiments of present invention provide forming a top electrode 430 in contact with both the first and the second top source/drain regions 412 and 422. The top electrode 430 may be formed through a subtractive patterning process or a damascene deposition process. More dielectric material may be added onto the dielectric layer 280 such that the top electrode 430 may be embedded in the dielectric layer 280.

In one embodiment, the bottom electrode 221 is conductively connected to the line source/drain area 262 thereby connected to the first and the second bottom source/drain region 411 and 412. The top electrode 430 is conductively connected to the first and the second top source/drain region 412 and 422.

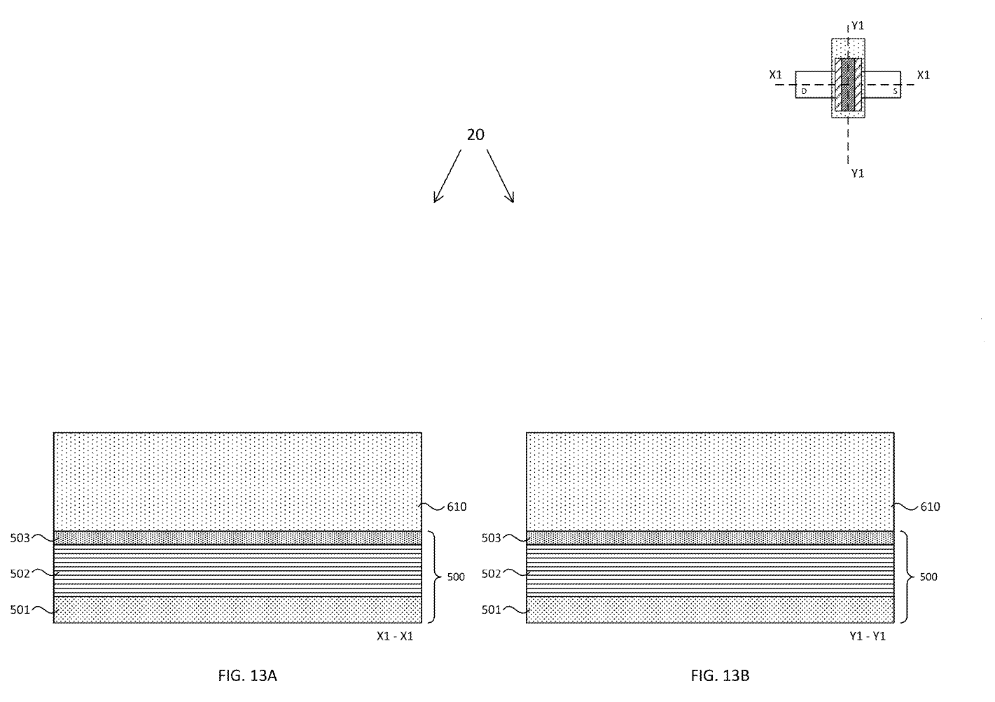

FIGS. 13A and 13B are demonstrative illustrations of cross-sectional views of a semiconductor structure at a step of manufacturing thereof according to another embodiment of present invention. More specifically, FIG. 13A illustrates a cross-sectional view of the semiconductor structure 20 with a cross-section made along a dashed line X1-X1 as illustrated in a simplified top view of the semiconductor structure 20 at the up-right corner of the drawing. FIG. 13B illustrates a cross-sectional view of the semiconductor structure 20 with a cross-section made along a dashed line Y1-Y1, as illustrated in the simplified top view, and made in a direction perpendicular to the cross-section illustrated in FIG. 13A.

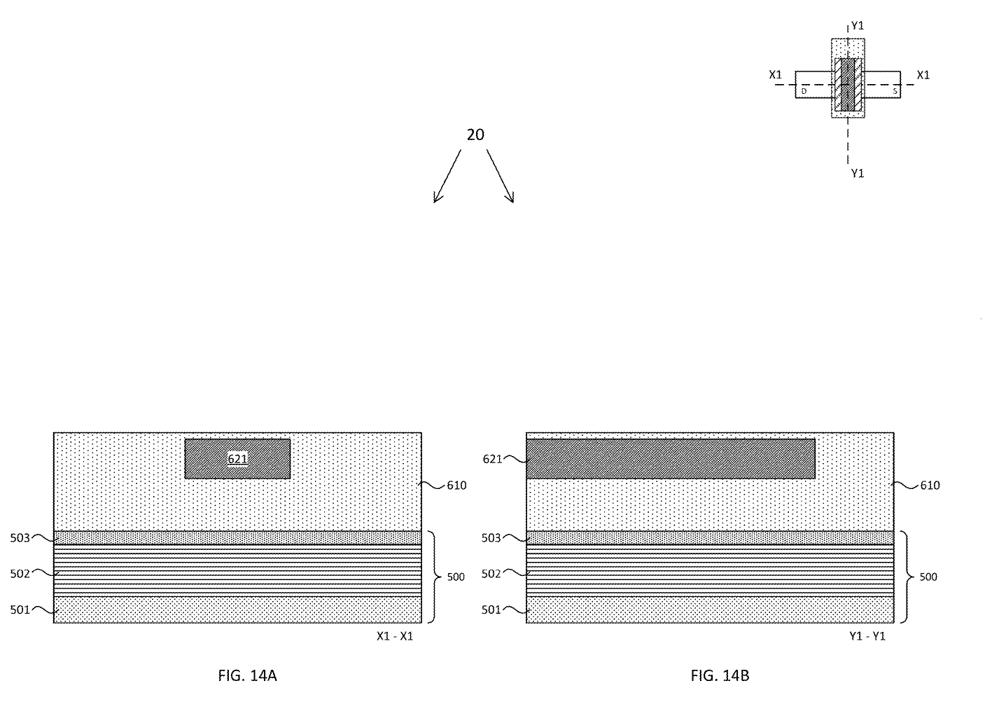

Likewise, FIGS. 14A and 14B- 21A and 21B are demonstrative illustrations of cross-sectional views of the semiconductor structure 20, at different manufacturing steps, that are illustrated in manners similar to FIGS. 13A and 13B respectively

More particularly, embodiments of present invention provide forming a semiconductor structure 20 that is demonstratively illustrated to start with a supporting structure 500. Similar to the supporting structure 100 in the semiconductor structure 10, the supporting structure 500 may include, for example, a substrate 501 and a BEOL stack 502 on top of the substrate 501, and a capping layer 503 on top of the BEOL stack 502. The capping layer 503 may include or be made of, for example, SiN.

Embodiments of present invention further provide forming a dielectric layer 610 on top of the capping layer 503. The dielectric layer 610 may be a silicon-oxide layer and may be formed through a deposition process such as, for example, a CVD process, a PVD process, an ALD process, or other currently existing or future developed deposition process.

FIGS. 14A and 14B are demonstrative illustrations of cross-sectional views of a semiconductor structure at a step of manufacturing thereof, following the step illustrated in FIGS. 13A and 13B, according to one embodiment of present invention. More particularly, embodiments of present invention provide forming a backside electrode 621 to be embedded in the dielectric layer 610. The backside electrode 621 may be formed, for example, through a damascene process by creating a trench in the dielectric layer 610 first, filling the trench with a conductive material to form the backside electrode 621, applying a CMP process to planarize a top surface thereof, and depositing additional dielectric material on top of and covering the backside electrode 621. However, embodiments of present invention are not limited in this aspect. For example, the backside electrode 621 may be formed through a subtractive patterning process.

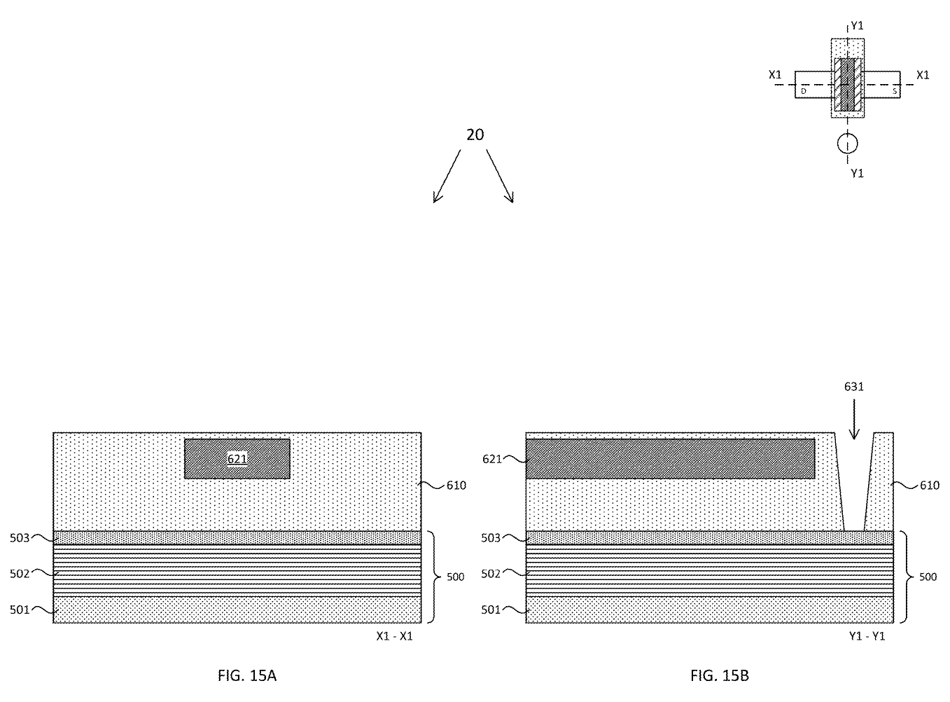

FIGS. 15A and 15B are demonstrative illustrations of cross-sectional views of a semiconductor structure at a step of manufacturing thereof, following the step illustrated in FIGS. 14A and 14B, according to one embodiment of present invention. More particularly, embodiments of present invention provide creating an opening 631 in the dielectric layer 610. The opening 631 may be created through a lithographic patterning and selective etch process. The opening 631 may expose a top surface of the capping layer 503.

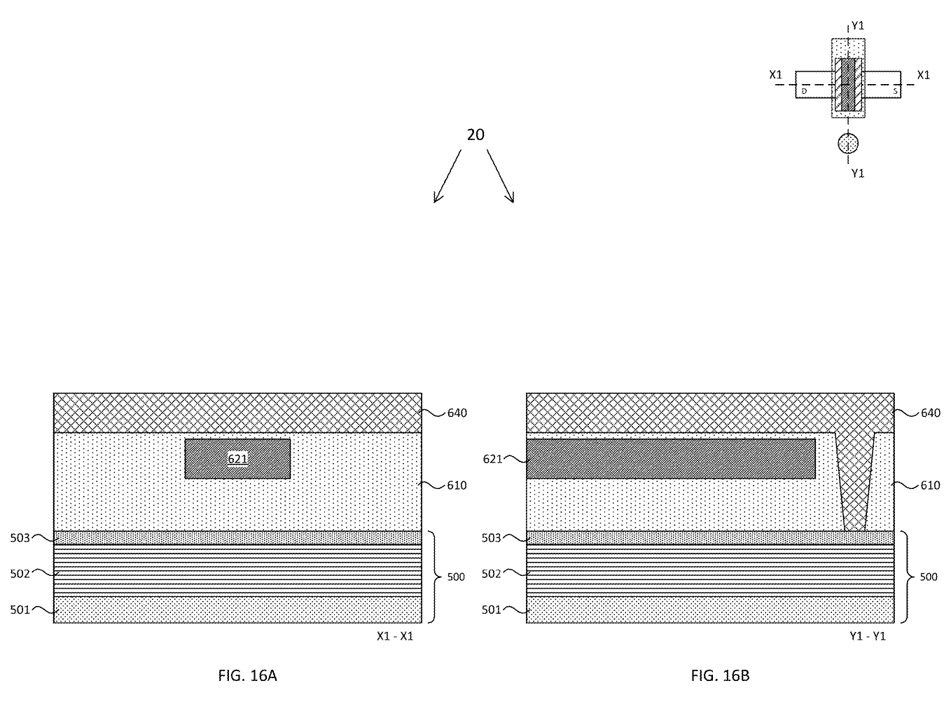

FIGS. 16A and 16B are demonstrative illustrations of cross-sectional views of a semiconductor structure at a step of manufacturing thereof, following the step illustrated in FIGS. 15A and 15B, according to one embodiment of present invention. More particularly, embodiments of present invention provide depositing amorphous silicon in the opening 631 and on top of the dielectric layer 610 thereby forming an amorphous silicon layer 640. The amorphous silicon layer 640 may be deposited through, for example, a PVD process, a CVD process, or an ALD process. After the deposition, either p+ or n- ion implantation may be performed to dope the amorphous silicon layer 640 such that materially the amorphous silicon layer 640 may become suitable for forming either p-type or n-type semiconductor transistors.

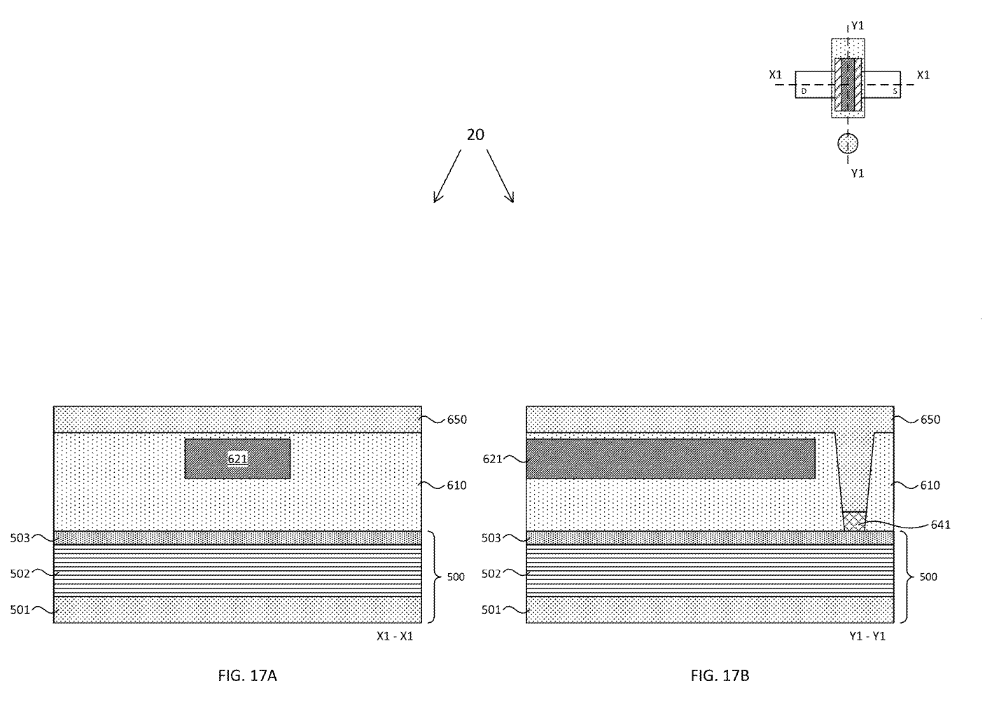

FIGS. 17A and 17B are demonstrative illustrations of cross-sectional views of a semiconductor structure at a step of manufacturing thereof, following the step illustrated in FIGS. 16A and 16B, according to one embodiment of present invention. More particularly, embodiments of present invention provide crystalizing the amorphous silicon layer 640 through an annealing process such as a rapid laser annealing process. The crystallization process may turn the amorphous silicon layer 640 and, for example, more than half of the amorphous silicon in the opening 631 into a crystalline silicon layer 650 with only a fraction 641 of the amorphous silicon remaining at the bottom of the opening 631. Material of the fraction 641 of the amorphous silicon, except being in an amorphous state, is substantially same as material of the crystalline silicon layer 650. After the crystallization, a CMP process may be applied to planarize a top surface of the crystalline silicon layer 650.

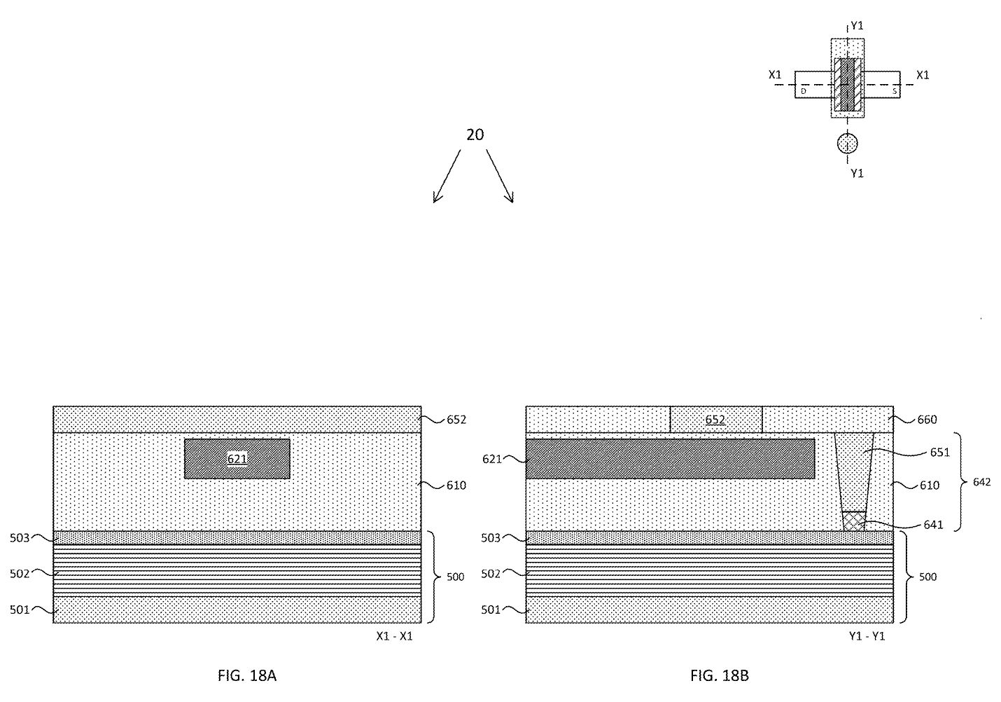

FIGS. 18A and 18B are demonstrative illustrations of cross-sectional views of a semiconductor structure at a step of manufacturing thereof, following the step illustrated in FIGS. 17A and 17B, according to one embodiment of present invention. More particularly, embodiments of present invention provide patterning the crystalline silicon layer 650 on top of the backside electrode 621 into a silicon layer 652 such that the silicon layer 652 may serve to form a channel region of a planar transistor to be formed on top thereof. The patterning may leave a fraction 651 of the crystalline silicon in the opening 631 on top of the fraction 641 of the amorphous silicon. Next, dielectric material may be deposited to form a dielectric layer 660 on top of the dielectric layer 610 and the silicon layer 652 may become embedded in the dielectric layer 660. In one embodiment, the patterning may create a via 642 embedded in the dielectric layer 610. The via 642 may include the fraction 641 of the amorphous silicon and the fraction 651 of the crystalline silicon and may be at a level below the silicon layer 652.

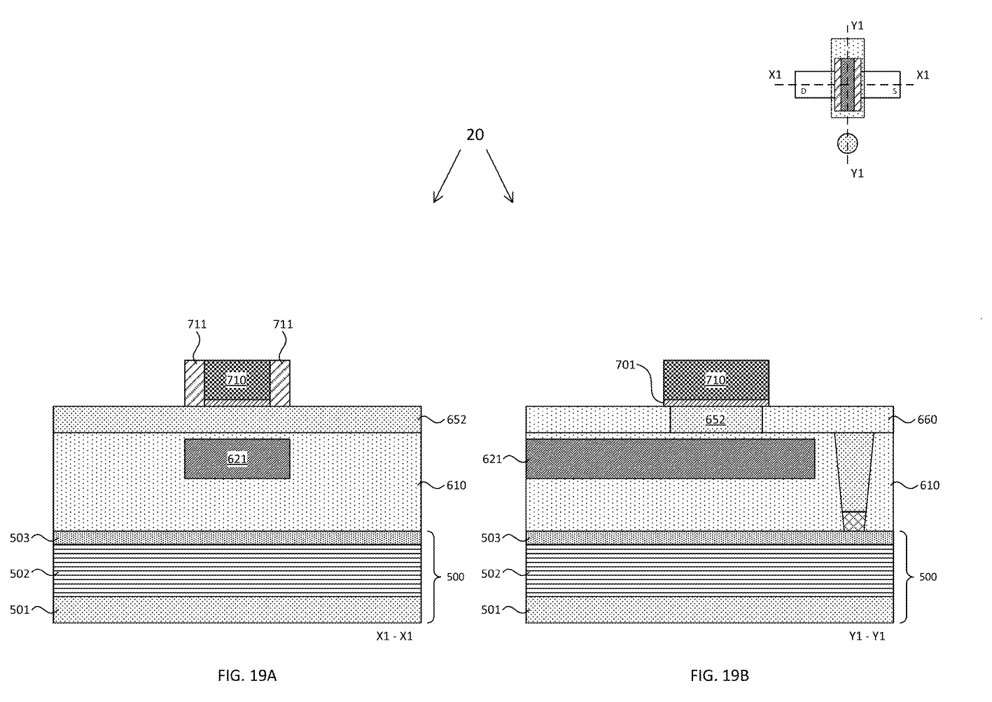

FIGS. 19A and 19B are demonstrative illustrations of cross-sectional views of a semiconductor structure at a step of manufacturing thereof, following the step illustrated in FIGS. 18A and 18B, according to one embodiment of present invention. More particularly, embodiments of present invention provide depositing a gate dielectric layer on top of the silicon layer 652 and a gate metal layer on top of the gate dielectric layer. Next, embodiments of present invention include patterning the gate metal layer and the gate dielectric layer, through for example a lithographic patterning process, to form a metal gate 710 on top of a gate dielectric 701. In one embodiment, the gate dielectric 701 may include high-k dielectric materials such as, for example, HfOx and the metal gate 710 may include, for example, W, Co, Cu, TiN, and/or other suitable conductive materials. After forming the metal gate 710, sidewall spacers 711 may be formed at sidewalls of the metal gate 710. The sidewall spacers 711 may include or be made of dielectric materials such as, for example, SiN, SiOx, or other suitable materials. The sidewall spacers 711 may be formed through, for example, forming a dielectric layer conformally surrounding the metal gate 710. Next, a directional etch process such as a RIE process may be applied to remove horizontal portions of the conformal dielectric layer thereby leaving only vertical portions of the conformal dielectric layer at sidewalls of the metal gate 710. The vertical portions of the conformal dielectric layer then form the sidewall spacers 711.

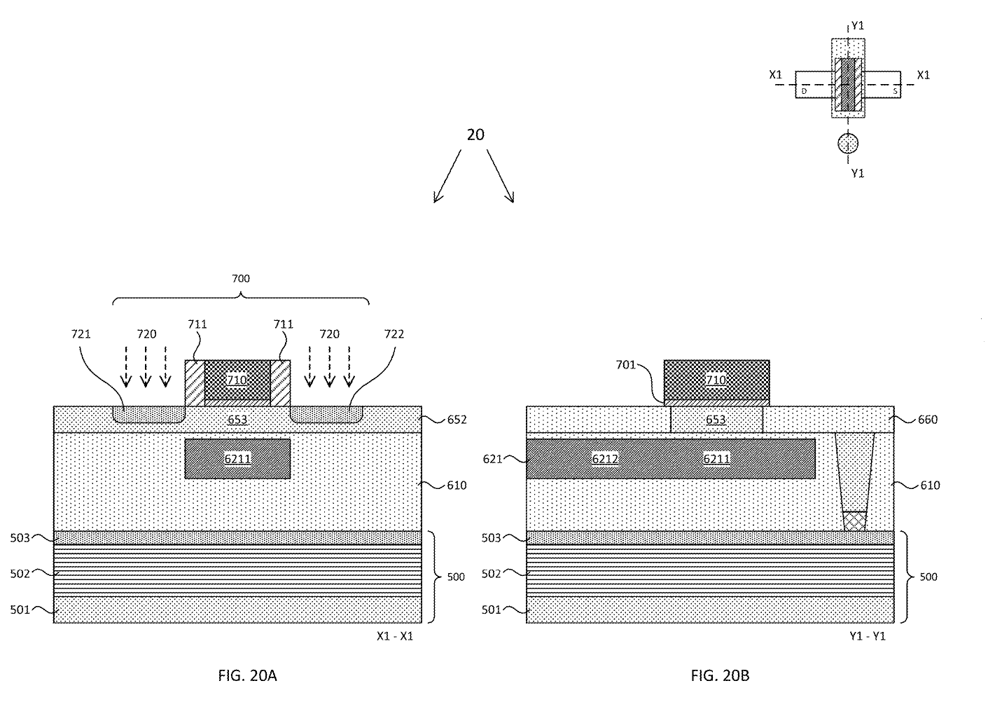

FIGS. 20A and 20B are demonstrative illustrations of cross-sectional views of a semiconductor structure at a step of manufacturing thereof, following the step illustrated in FIGS. 19A and 19B, according to one embodiment of present invention. More particularly, embodiments of present invention provide forming a first source/drain region 721 and a second source/drain region 722 by performing either p+ or n- (depending on the type of transistor to be formed) ion implantation 720 in regions adjacent to the sidewall spacers 711, thereby forming a planar transistor 700. The planar transistor 700 may include a metal gate 710, a channel region 653 directly underneath the metal gate 710 via the gate dielectric 701, a backside electrode 621 directly underneath the channel region 653, and the source/drain regions 721 and 722. The channel region 653 may be formed from a portion of the silicon layer 652.

The backside electrode 621 may include a first portion 6211 and a second portion 6212. The first portion 6211 of the backside electrode 621 may be, or serve as, a back-gate of the planar transistor 700, and the second portion 6212 may be, or serves as, an electrical contact in direct contact with the back-gate of the planar transistor 700.

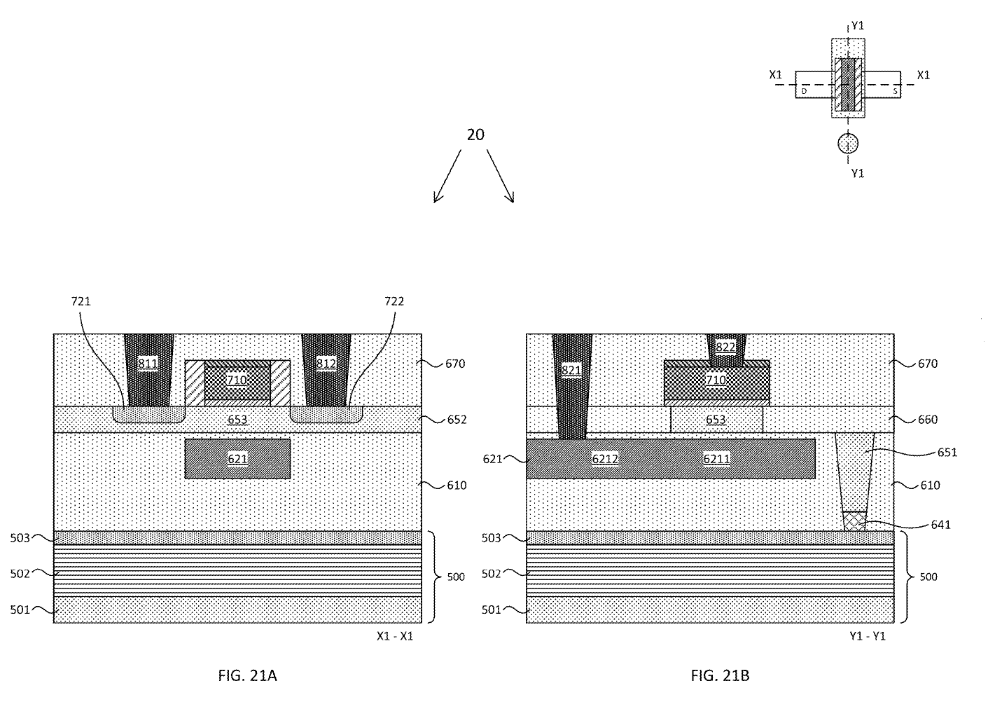

FIGS. 21A and 21B are demonstrative illustrations of cross-sectional views of a semiconductor structure at a step of manufacturing thereof, following the step illustrated in FIGS. 20A and 20B, according to one embodiment of present invention. More particularly, embodiments of present invention provide optionally forming a capping layer on top of the metal gate 710 and depositing dielectric material to form a dielectric layer 670 on top of and surrounding the planar transistor 700 such that the planar transistor 700 may be embedded in the dielectric layer 670.

Next, various contacts may be formed to be in contact with the planar transistor 700. For example, a first and a second source/drain contacts 811 and 812 may be formed through the dielectric layer 670 in contact with the first and the second source/drain regions 721 and 722. An electrode contact 821 may be formed through the dielectric layers 670 and 660 to be in contact with the backside electrode 621, which includes a first portion 6211 of the back-gate of the planar transistor 700 and a second portion 6212 of an electrical contact. A gate contact 822 may be formed through the dielectric layer 670 and a possible capping layer to be in contact with the metal gate 710.

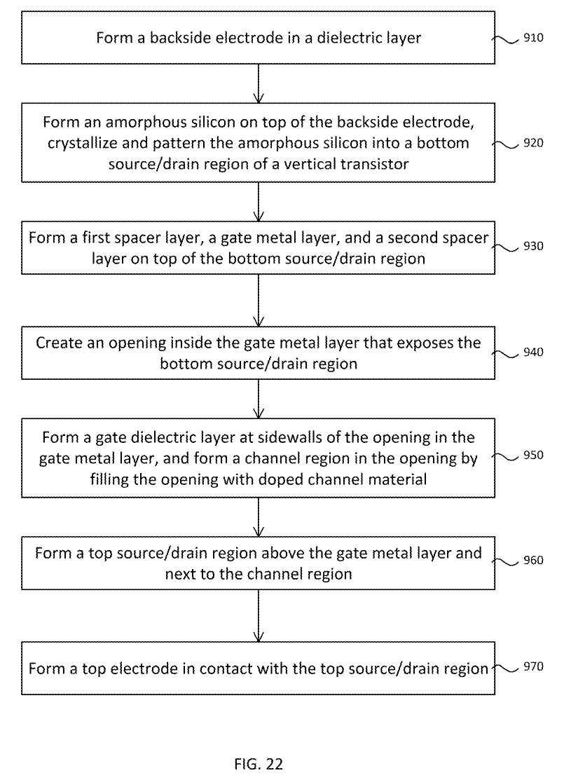

FIG. 22 is a demonstrative illustration of a flow-chart of a method of manufacturing a semiconductor structure according to embodiments of present invention. The method includes (910) forming a backside electrode in a dielectric layer; (920) forming an amorphous silicon on top of the backside electrode, and crystallizing and patterning the amorphous silicon into a bottom source/drain region of a vertical transistor; (930) forming a first spacer layer, a gate metal layer, and a second spacer layer subsequently on top of the bottom source/drain region; (940) creating an opening inside the gate metal layer that exposes the bottom source/drain region; (950) forming a gate dielectric layer at sidewalls of the opening in the gate metal layer, and forming a channel region in the opening by filling the opening with doped channel material; (960) forming a top source/drain region above the gate metal layer and next to the channel region; and (970) forming a top electrode in contact with the top source/drain region.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a field-effect-transistor (FET) embedded in a dielectric layer on top a back-end-of-line stack; and
one or more electrodes conductively connected to the FET,
wherein a first electrode of the one or more electrodes is directly underneath a layer of crystallized semiconductor material.

2. The semiconductor structure of claim 1, wherein the FET is a vertical FET and the first electrode is conductively connected to a source/drain region of the vertical FET, the source/drain region being formed in the layer of crystallized semiconductor material.

3. The semiconductor structure of claim 2, wherein the first electrode is in direct contact with a diffusion barrier layer, and the diffusion barrier layer is in direct contact with the layer of crystallized semiconductor material.

4. The semiconductor structure of claim 1, wherein the FET is a planar FET and the first electrode includes an electrical contact and a back-gate of the planar FET in direct contact with the electrical contact.

5. The semiconductor structure of claim 4, wherein the back-gate of the planar FET is vertically underneath a channel region of the planar FET.

6. The semiconductor structure of claim 1, further comprising a via embedded in the dielectric layer at a level below the layer of crystallized semiconductor material, the via comprises at least one material that is substantially same as the crystallized semiconductor material.

7. The semiconductor structure of claim 6, wherein the via further comprises a material in an amorphous state, the material, except being in the amorphous state, being substantially same as the crystallized semiconductor material.

8. A method of forming a semiconductor structure comprising:
providing a supporting structure, the supporting structure including a substrate and a back-end-of-line stack;
forming a backside electrode in a dielectric layer on top of the supporting structure;
forming an amorphous silicon layer on top of the backside electrode and crystallizing the amorphous silicon layer into a crystalline silicon layer;
patterning the crystalline silicon layer into a first part of a transistor;
forming a metal gate on top of the crystalline silicon layer; and
finishing forming the transistor.

9. The method of claim 8, wherein the transistor is a vertical transistor and the first part is a first source/drain region, and wherein forming the metal gate comprises:
forming a first spacer layer on top of the crystalline silicon layer;
forming a gate metal layer on top of the first spacer layer;
forming a second spacer layer on top of the gate metal layer;
creating an opening inside the gate metal layer, the opening exposing the first source/drain region;
forming a gate dielectric at sidewalls of the opening inside the gate metal layer; and
forming a channel region by filling the opening with doped channel material.

10. The method of claim 9, wherein finishing forming the transistor comprises:
forming a second source/drain region above the gate metal layer and next to the channel region; and
forming a top electrode in contact with the second source/drain region of the vertical transistor.

11. The method of claim 8, wherein the transistor is a planar transistor and the first part is a channel region of the planar transistor, and wherein forming the metal gate comprises:
forming a gate dielectric layer on top of the channel region;
forming a gate metal layer on top of the gate dielectric layer;
patterning the gate metal layer and the gate dielectric layer into a metal gate; and
forming sidewall spacers at sidewalls of the metal gate.

12. The method of claim 11, wherein finishing forming the transistor comprises:
forming a first and a second source/drain region in the crystalline silicon layer adjacent to the sidewall spacers;
covering the first and the second source/drain region with a layer of dielectric material;
forming a first and a second source/drain contact in contact with the first and the second source/drain region respectively;
forming a backside contact in contact with the backside electrode; and
forming a gate contact in contact with the metal gate of the planar transistor.

13. A semiconductor structure comprising:
a field-effect-transistor (FET) embedded in a dielectric layer on top of a substrate; and
one or more electrodes conductively connected to the FET,
wherein a first electrode of the one or more electrodes is directly underneath a layer of crystallized material and a portion of the layer of crystallized material is a part of the FET.

14. The semiconductor structure of claim 13, wherein the FET is a vertical FET and the first electrode is conductively connected to a bottom source/drain region of the vertical FET, and the portion of the layer of crystallized material forms the bottom source/drain region.

15. The semiconductor structure of claim 14, wherein the first electrode is conductively connected to the bottom source/drain region of the vertical FET via a diffusion barrier layer, the diffusion barrier layer containing WN, TiN, or TaN.

16. The semiconductor structure of claim 13, wherein the FET is a planar FET and the first electrode includes an electrical contact and a back-gate of the planar FET in direct contact with the electrical contact.

17. The semiconductor structure of claim 16, wherein the back-gate of the planar FET is vertically underneath a channel region of the planar FET and is formed from a portion of the first electrode.

18. The semiconductor structure of claim 13, further comprising a via embedded in a dielectric layer at a level below the layer of crystallized material, the via comprises at least one material that is substantially same as the crystallized material.

19. The semiconductor structure of claim 18, wherein the via further comprises a material in an amorphous state, the material, except being in the amorphous state, being substantially same as the crystallized material.

20. The semiconductor structure of claim 19, wherein the crystallized material is a crystallized silicon or a crystallized silicon-germanium.
